(19) United States
(12) Patent Application Publication
(10) Pub. No.: US 2024/0080023 A1
(43) Pub. Date: Mar. 7, 2024

(54) HIGH TRACKING BANDWIDTH REFERENCE GENERATOR CIRCUIT

(71) Applicant: Mellanox Technologies Ltd., Yokneam (IL)

(72) Inventor: Boris SHARAV, Yokneam (IL)

(73) Assignee: Mellanox Technologies Ltd., Yokneam (IL)

(21) Appl. No.: 17/903,165

(22) Filed: Sep. 6, 2022

(51) Int. Cl. H03K 5/24

(52) U.S. Cl. CPC H03K 5/24

(57) ABSTRACT

An electronic circuit may include at least two capacitors arranged in parallel; at least two resistors arranged in series; a positive supply voltage connected to the resistors; a negative supply voltage connected to the resistors, the resistors producing a reference signal; a source circuit producing a source signal and connected to the positive supply voltage and negative supply voltage; and a receiving circuit connected to the positive supply voltage and negative supply voltage, and receiving the source signal and reference signal.

### FIELD OF THE DISCLOSURE

The present invention relates to the field of minimizing duty cycle distortion, for example distortion in front of a sampling comparator at ultra-short reach links caused by supply noise due to resonance in an electronic circuit package.

### BACKGROUND OF THE INVENTION

A clocked comparator is a common building block in an analog to digital converter (ADC) and in communication links. When the clock comparator receives a single ended signal, the clock comparator compares the signal value to known reference value. The circuit decides if the signal is above or beyond the reference and generates a digital “1” or “0” output.

In low power complementary metal-oxide-semiconductor (CMOS) based architectures, the signal's amplitude and edge crossings are modulated by the medium frequency supply noise in the range of 10-100 Megahertz which may be caused by the package resonance. When such a supply modulated single ended signal is compared to reference circuit in front of a comparator, the comparator reference circuit may need to maintain two contradictory functions. Signal envelope tracking may be performed by the reference to maintain the reference located at the middle of supply modulated signal, which if not maintained may cause the reference point to be not located at the middle, and cause duty cycle distortion. Reducing kickback noise may be performed by presenting low impedance to a comparator at reference node, which if not maintained may cause the comparator to suffer from DC offsets, which cause supply and temperature dependent duty cycle distortion (DCD).

Approaches to solve the voltage tracking problem include for example finding a compromise between signal envelope tracking and reducing kickback noise; generating supply independent signals such that the reference node should not track the supply to be located at correct voltage values; use of complex circuitry and additional power to stabilize the signal supply up to required frequency; and generating high signal slopes and reduce errors by minimizing amplitude variations (AM) to phase deviation (PM) conversion, which usually costs power to drive sharp transitions.

### SUMMARY OF THE INVENTION

An electronic circuit may include at least two capacitors arranged in parallel from the point of a reference output; at least two resistors arranged in series; a positive supply voltage connected to the resistors; a negative supply voltage connected to the resistors, the resistors producing a reference signal; a source circuit producing a source signal and connected to the positive supply voltage and negative supply voltage; and a receiving circuit connected to the positive supply voltage and negative supply voltage, and receiving the source signal and reference signal.

Embodiments include a reference generator (RefGen) design which may minimize duty cycle distortion of the signal in front of a sampling comparator by forcing the reference voltage to track signal's envelope and overcome supply dynamic variations originating from package resonance. Embodiments may maintain both functions of signal envelope tracking and reducing kickback noise with very low power consumption from a reference generated circuit.

In some embodiments an all-pass filter circuit may perform high tracking bandwidth to facilitate a sampling link architecture. Such a circuit may minimize duty cycle distortion e.g. caused by resonance in an electronic circuit package. An all-pass filter may include an arrangement of resistors and capacitors and may also incorporate a resistor ladder. Such a circuit may be used in, for example, for direct sampling link architecture at silicon interposers.

### BRIEF DESCRIPTION OF THE DRAWINGS

Non-limiting examples of embodiments of the disclosure are described below with reference to figures. Identical features that appear in more than one figure are generally labeled with a same label in all the figures in which they appear. Dimensions of features shown in the figures are chosen for convenience and clarity of presentation and are not necessarily shown to scale. For example, the dimensions of some of the elements may be exaggerated relative to other elements for clarity, or several physical components may be included in one functional block or element. Embodiments of the invention are illustrated by way of example and not limitation in the figures of the accompanying drawings.

FIG. 1 presents a transmitter sending a signal over a short channel to the receiver or sampler according to some embodiments.

FIG. 2 presents example waveforms of a transmitter output modulated by supply noise of one embodiment of the invention.

FIG. 3 presents a close look in a resolution of several bits of one embodiment of the invention.

FIG. 4 presents a tracking reference and non-tracking reference of one embodiment of the invention.

FIG. 5 presents zooming into the regions where positive voltage supply (VDD) is located at maximum value according to one embodiment.

FIG. 6 presents zooming into the regions where VDD in FIG. 2 is located at a minimum value in one embodiment of the invention.

FIG. 7 presents the DCD impact of tracking reference against non-tracking reference according to one embodiment.

FIG. 8 presents a relatively simple reference generation circuit according to some embodiments.

FIG. 9 is a diagram of a circuit according to one embodiment of the invention.

FIG. 10 presents a best effect of the DCD variation peak-to-peak (p-p) value for the DCD waveform in of one embodiment of the invention.

FIG. 11 presents a potential offset problem which may require a reference trimming circuit of one embodiment of the invention.

FIG. 12 presents a simple configuration in which the reference value can be chosen from resistor ladder of one embodiment of the invention.

FIG. 13 presents a ladder in which N different voltage values can be selected by ‘sel’ control according to one embodiment.

FIG. 14 presents an all pass filter structure with multiple outputs of one embodiment of the invention.

FIG. 15 presents an example implantation where a number of client circuits can accept a reference from a number of decoders connected to one resistor ladder, according to one embodiment of the invention.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes. Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term set when used herein may include one or more items. Unless explicitly stated, the method embodiments described herein are not constrained to a particular order or sequence. Additionally, some of the described method embodiments or elements thereof can occur or be performed simultaneously, at the same point in time, or concurrently.

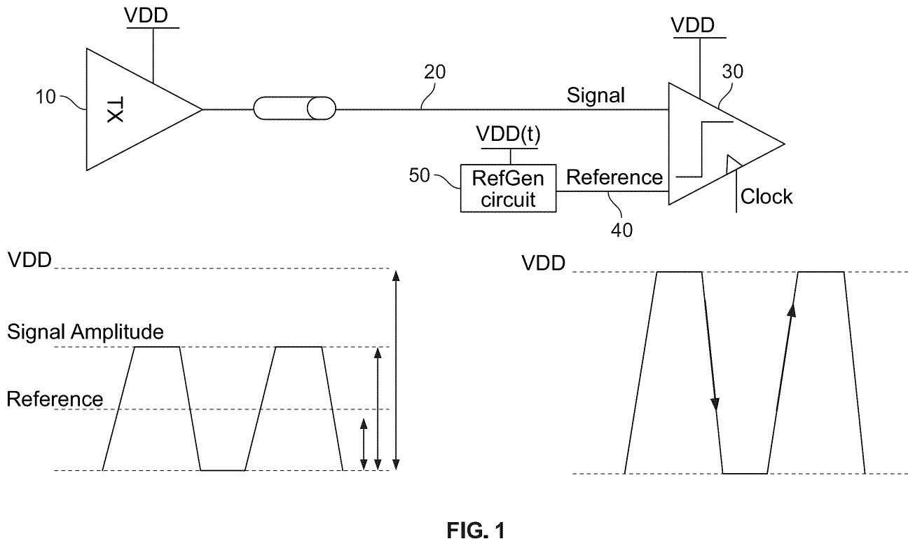

FIG. 1 presents a transmitter or source circuit 10, e.g. with a supply-based amplitude, connected to negative voltage supply (VSS) and VDD, and producing or sending a source signal 20 over a short channel to a receiver sampler, comparator or other receiving circuit 30, according to one embodiment. On every clock edge, whether it be rising or falling, sampler 30 may compare signal 20 to the reference signal or output 40, which is generated by a RefGen circuit 50, and amplifies the voltage difference to digital levels. Receiving circuit 30 may be connected to VDD and VSS, and may receive the source signal and reference signal. The amplitude of signal 20 at the transmitter 10 output is a well known fraction of the VDD such as 0.5*VDD. The receiver reference voltage in one example should be half of the amplitude of signal 20, such as 0.25*VDD for a 0.5*VDD signal amplitude, in order to be located exactly at the middle of or substantially in the middle of the signal. The channel may be short enough and the supply of the transmitter and the receiver may be approximately the same at medium frequency range of for example 10 to 100 Megahertz.

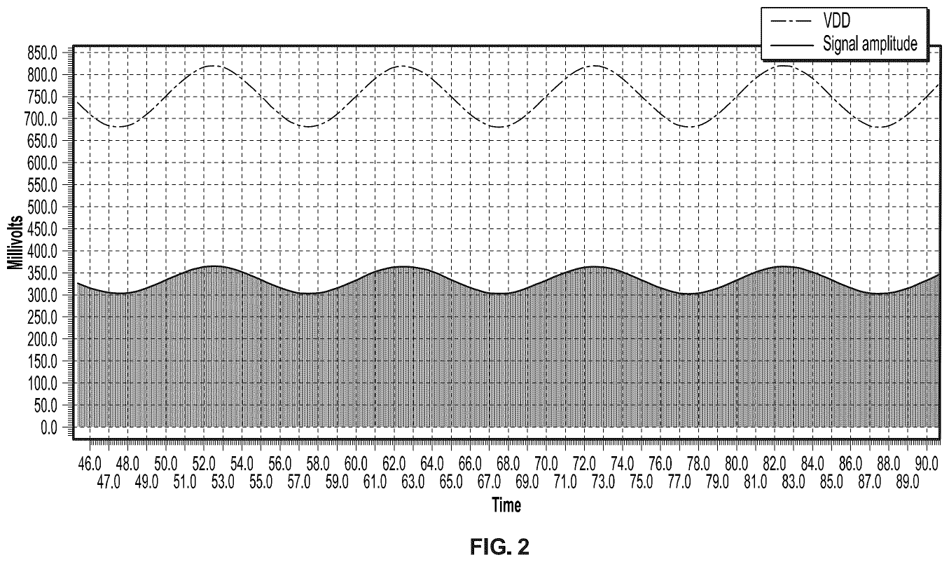

FIG. 2 presents example waveforms of a transmitter output modulated by supply noise according to one embodiment, showing amplitude modulation, where the supply VDD has a medium frequency ripple at 100 Megahertz. The signal rate is 16 GBps and its amplitude is 0.5 or a ½ fraction of VDD. Since the signal is directly modulated by the supply, its amplitude also presents the VDD ripple. The X axis represents time and the Y axis represents millivolts.

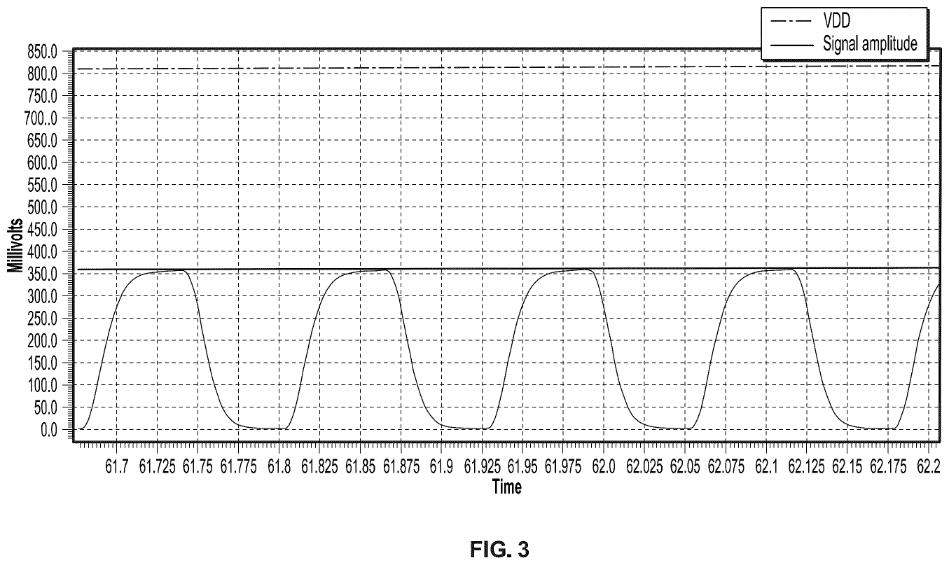

FIG. 3 presents a close look in a resolution of several bits, e.g. with signal amplitude modulation, according to one embodiment. When the receiver tries to sample the bits under signal conditions previously presented, in one example, it should use tracking reference rather than non-tracking reference. The X axis represents time and the Y axis represents millivolts.

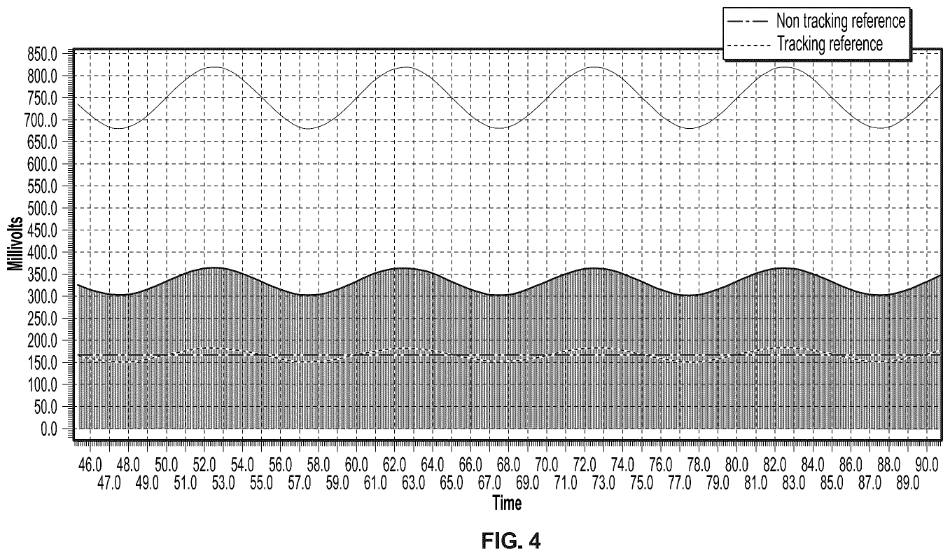

FIG. 4 presents a tracking reference and non-tracking reference according to one embodiment. The tracking reference changes together with the supply such that in one example it is always half of signal amplitude. The non-tracking reference may be higher than the ideal crossing point when the supply instantaneously low and may be below the ideal crossing point when the supply instantaneously high. The X axis represents time and the Y axis represents millivolts.

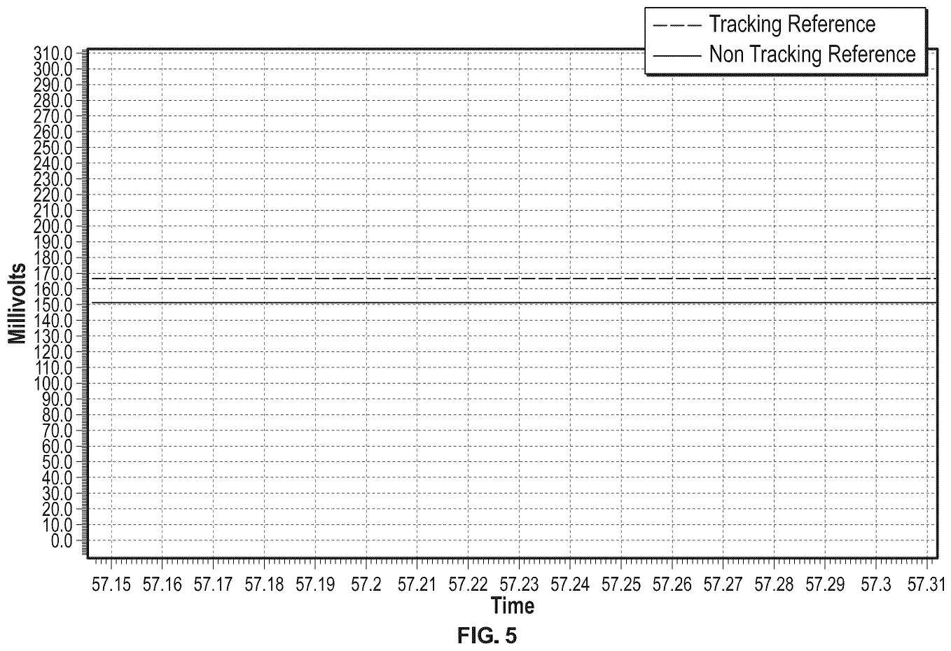

FIG. 5 presents a zoom into the regions where VDD in FIG. 2 is located at maximum value according to one embodiment. The X axis represents time and the Y axis represents millivolts.

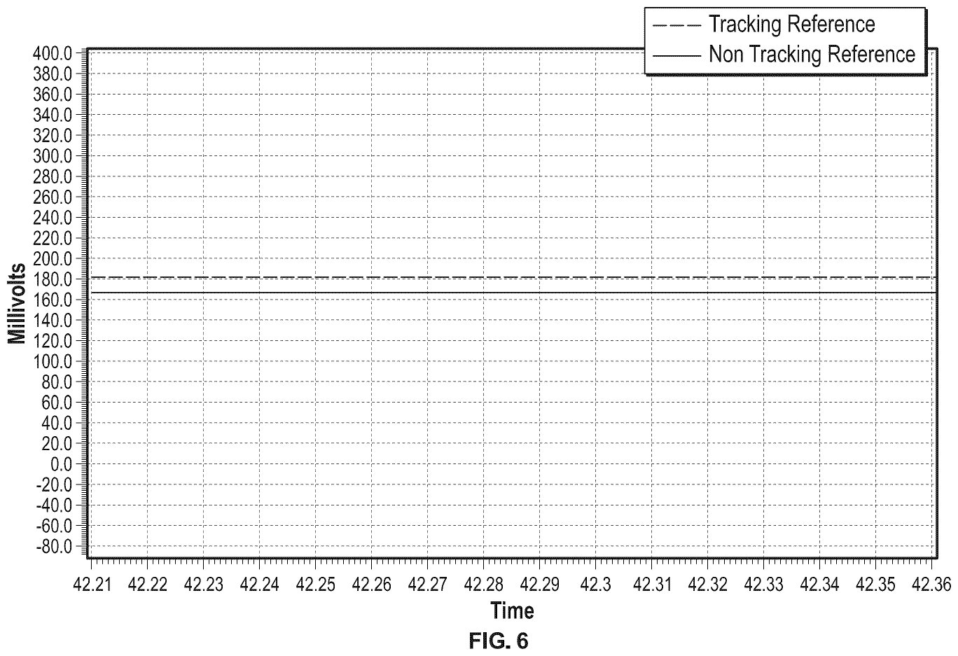

FIG. 6 presents an expanded view into the regions where VDD in FIG. 2 is located at a minimum value according to one embodiment. In order to quantify the non-tracking reference effect, duty cycle distortion (DCD) is measured on a waveform using a signal reference comprising a subtraction of signal's voltage and reference's voltage. The X axis represents time and the Y axis represents millivolts.

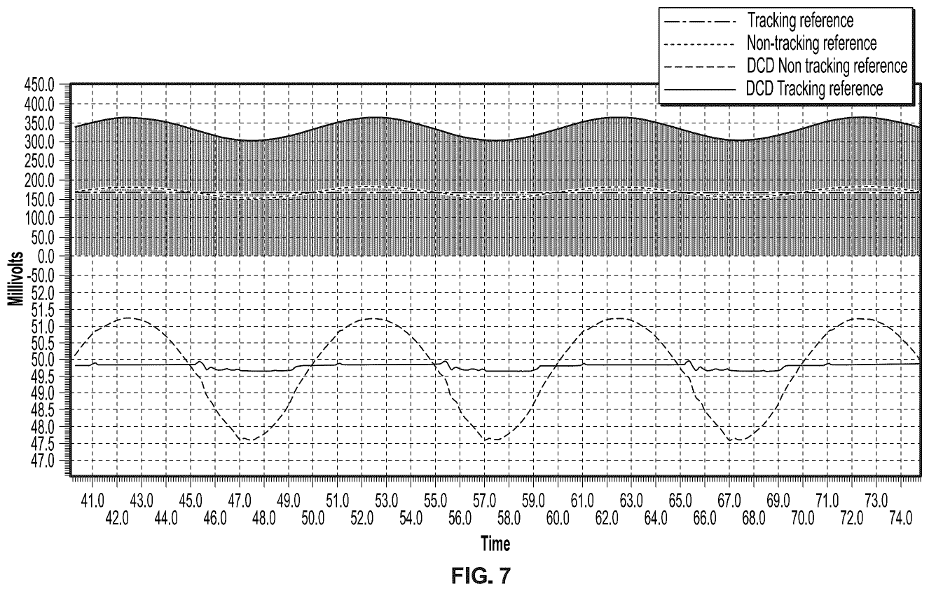

FIG. 7 presents the DCD impact of tracking reference against non-tracking reference according to one embodiment. It can be seen that a non-tracking reference 700 may introduce supply dependent DCD where a tracking reference 710 shows no dependence on VDD. In order to avoid a DCD effect, a RefGen circuit in one embodiment may generate a tracking reference. The X axis represents time and in the upper portion the Y axis represents millivolts, and in the lower portion the Y axis represents percentage of time that the output is 1 with respect to a reference (tracking or non-tracking), such that a lower percentage means that 0 is more represented.

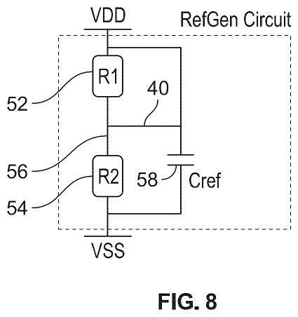

FIG. 8 presents a relatively simple reference generation circuit according to some embodiments. For resistors 52 and 54, a resistor divider 56 (e.g. an output line or wire connected at the point the two resistors are electrically connected to each other) is used to set the reference value, signal or output 40 to exactly or substantially half of the desired signal's amplitude such that, in one example:

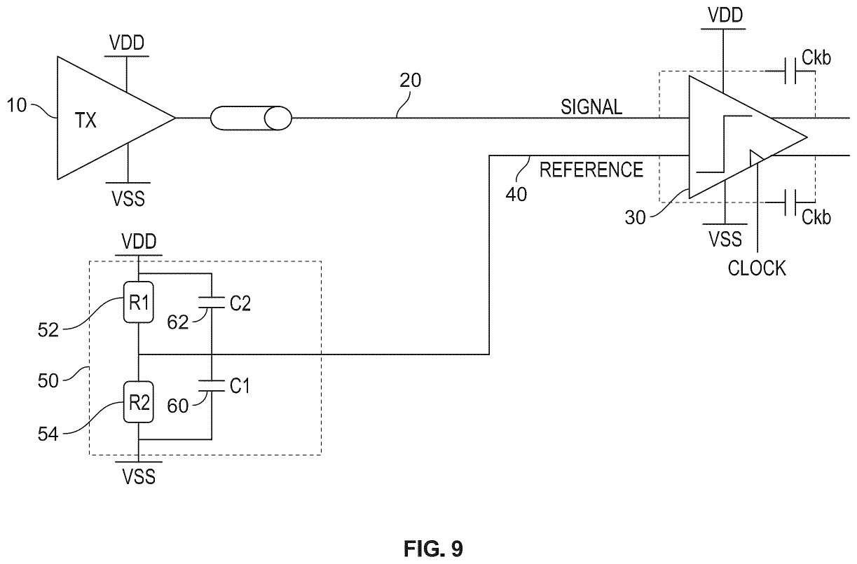

REFERENCE=VDD×R2/(R1+R2)=0.5*Signal amplitude

where REFERENCE is the desired reference value or signal 40, R1=the value in ohms of resistor 52, R2=the value in ohms of resistor 54, and Signal amplitude=the amplitude of source signal 20. The values of R1 resistor 52 and R2 resistor 54 may be in the range of several kilo Ohms to limit the current consumption of RefGen (I=VDD/(R1+R2), where I=current). However, in such topology a clocked comparator may require ‘Cref’ capacitor 58 to absorb kickback noise which originates from ‘Ckb’ parasitic capacitance between comparators' input and output (e.g. comparator 30 of FIG. 9). The presence of ‘Cref’ capacitor together with resistor divider 56 may form a Low Pass Filter (LPF) which suppresses the VDD ripple, forcing it to behave more like a non tracking reference rather than a tracking reference.

FIG. 9 is a diagram of a circuit according to one embodiment of the invention. In FIG. 9, a source circuit or transmitter 10 sends an output signal 20 to a receiver sampler, comparator or other receiving circuit 30. All of transmitter 10, receiver sampler 30, and RefGen circuit 50, may be connected to the same voltage VDD and voltage VSS. The circuit of FIG. 9 may maintain a large ‘Cref’ and high tracking bandwidth. Two or more resistors (only resistors 52 having R1 and 54 having R2 are shown for clarity) may be connected to each other or arranged in series, with VDD connected to one end of the series and VSS connected to another end of the series. Reference signal or output 40 may be produced by a signal or connection from in between two of resistors, e.g. output 40 may be connected to two of the resistors at a point not also connected directly to VDD or VSS, and also connected in-between capacitors 60 and 62, at the point where capacitors 60 and 62 are electrically connected to each other; thus in FIG. 9 resistors 52, 54 and capacitors 60 and 62 are electrically connected to each other. One embodiment forms an all pass filter (APF) rather than an LPF. Capacitor 60 having capacitance C1 and capacitor 62 having capacitance C2, arranged in parallel (parallel when viewed from the perspective of the comparator and output 40; although capacitors 60 and 62 are in series from the point of view of VDD), are included in RefGen circuit 50 producing reference signal, value or output 40. In FIG. 9, from the point of reference 40, resistor R1 is arranged in parallel to capacitor C2; this resistor and capacitor combination is arranged in series to another a resistor R2 in parallel to another capacitor C1. Within RefGen circuit 50, each set of the set of capacitors and the set of resistors may be connected to a common voltage VSS and VDD. In one embodiment the sizing ratio R1/R2=C1/C2 (e.g., with reference to positive or negative supply) may be maintained (R1 and R2 being resistance and C1 and C2 being capacitance), and APF may be formed. This example circuit presents capacitance equal to C1∥C2 (e.g. the parallel output of capacitors 60 and 62, indicating parallel operation) to comparator 30 and tracks VDD changes with the resistor divider at low frequencies and with capacitor divider at high frequencies. This example structure may track very high bandwidth while also maintaining low power consumption. In one embodiment, reference value 40 is substantially or exactly half, or in the middle, of output signal 20 (e.g. as shown in the graph comparing signal and reference in FIG. 1). The amplitude of signal 20 at the transmitter 10 output may be a known fraction of the VDD such as 0.5*VDD or another fraction.

A receiving circuit, such as a comparator or sampler 30, may sample its inputs, signal 20 and reference value 40, to produce an output, for example a digital signal which is 1 or 0, based on the comparison between signals 20 and 40. In order to sample correctly, reference 40 should be a correct value. If a supply, e.g. VDD, is noisy or varies over time, in one embodiment reference 40 may change to match the supply, and may change quickly. In order for this quick change, RefGen circuit 50 may track VDD using in part an additional one or more capacitors when compared to prior art circuits. RefGen circuit 50 may satisfy two conditions: tracking inputs quickly; and tracking accurately.

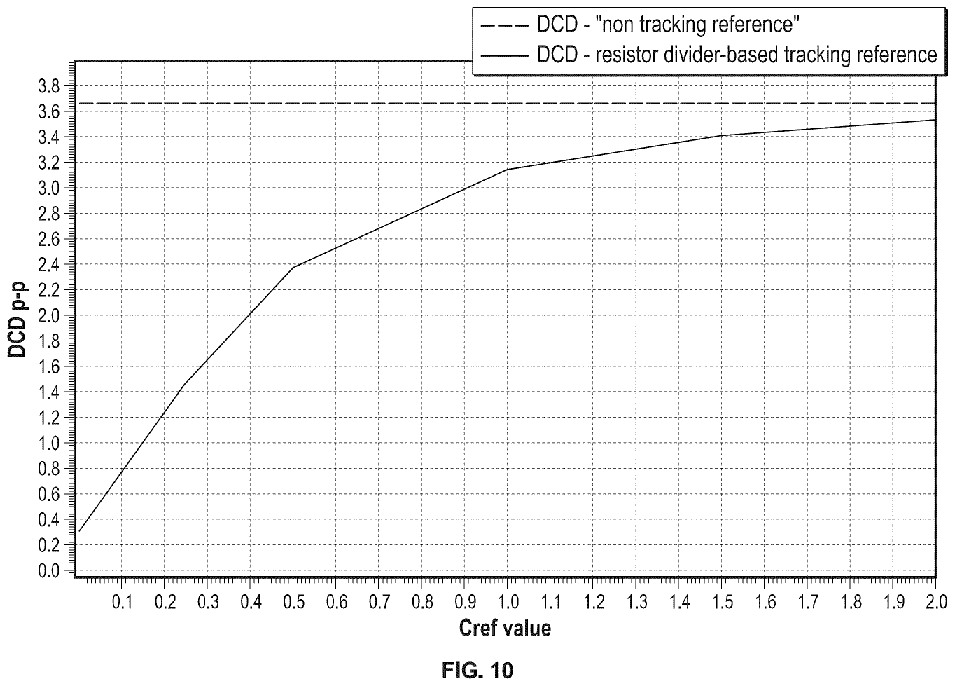

FIG. 10 presents a best effect of the DCD variation peak to peak value for the example DCD waveform of in FIG. 7, according to one embodiment, as the function of or dependence on a ‘Cref’ capacitor compared to non-tracking reference. FIG. 10 presents the dependance of DCD on Cref capacitor value in case of the more simple presented in FIG. 8. For low ‘Cref’ values the DCD peak to peak of a resistor divider's base reference are low compared to non-tracking case. However for high ‘Cref’ values the DCD peak to peak values are close to non-corrected reference case. A RefGen circuit with realistic ‘Cref’ values in the range of 0.3-1 pF and with low current consumption of the resistor divider ten of micro Amps may fail to track mid-frequency VDD noise. The X axis represents the Cref value in picofarads, and the Y axis represents DCD in percentage.

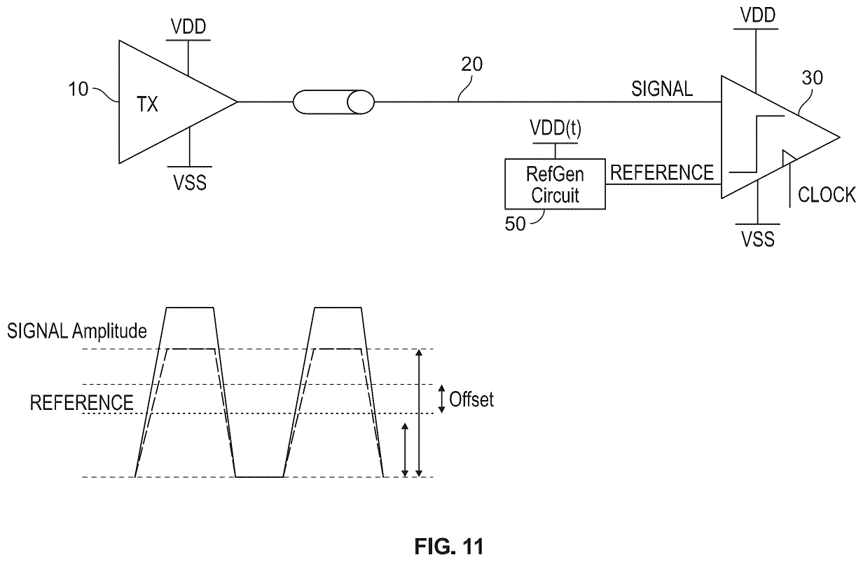

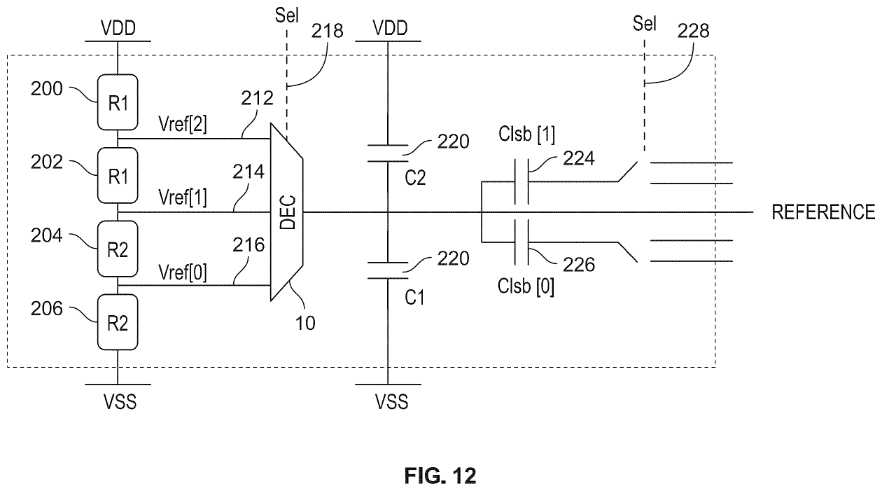

FIG. 11 presents a potential offset problem which may require a reference trimming circuit according to one embodiment. If the transmitter amplitude has an offset, then the reference value can be changed to be located exactly or substantially at the middle. FIG. 12 presents an example of a simple circuit in which the reference value can be chosen from resistor ladder, according to one embodiment.

In the arrangements of FIGS. 11 and 12, a device such as a decoder may be used to choose among voltages output in-between resistors.

Referring to FIG. 12, N resistors 200, 202, 204, and 206 (an example of four resisters are shown for clarity) are placed between VDD and VSS or source and provide output to a decoder 210. Resistors 200, 202, 204 and 206 may form a resistor ladder, and the reference value may be selected from a connection between two of the resistors. The values of the individual resistors may be selected such that the output of the decoder is half the signal amplitude. The choice, via decoder 210, of an output line from between sets of resistors, changes the ratio of two resistances, each resistance formed by resistor(s) on one side of the selected line. Changing the resistance ratio requires changing of the capacitance ratio, such that the ratio of the resistances is the same as the ratio of capacitances. Selection of different resistances may be to maintain different levels of output signals, due to, e.g. different input requirements of different equipment, or different manufacturing results or manufacturing errors of equipment. One of the N-1 (e.g., three if there are four resistors) available voltage values (e.g. 212, 214 and 216) output from the group of resistors can be selected chosen by for example a ‘sel’ control 218, or another circuit. The capacitor bank may include for example two constant capacitors C1 220 and C2 220 connected to Voltage Supply (VSS) and VDD respectively and two ‘Clsb’ capacitors 224 and 226. ‘Clsb’ capacitors 224 and 226 may be selectively controlled, e.g. capacitors' 224 and 226 connectivity may be controlled also by a ‘sel’ control 228. Selecting capacitors may result in a selection of both capacitors 224 and 226 connected to VDD, both capacitors 224 and 226 connected to VSS, or one of capacitors 224 and 226 connected to VDD and the other to VSS. The capacitors' and resistors' values may be chosen such that for each ‘sel’ code the ratio of equivalent resistance between the reference and VDD and the reference and VSS are equal to equivalent capacitance value between the reference and VSS and the reference and VDD.

If equivalent resistors/capacitors are defined as below, a truth table for each one of the three example cases may be presented:
Req(ref−vdd)—Equivalent resistance between reference and VDD
Req(ref−vss)—Equivalent resistance between reference and VSS
Ceq(ref−vdd)—Equivalent capacitance between reference and VDD
Ceq(ref−vss)—Equivalent capacitance between reference and VSS

TABLE 1

| Sel | | | | |
|---|---|---|---|---|
| Code | Req(ref-vdd) | Req(ref-vss) | Ceq(ref-vdd) | Ceq(ref-vss) |
| 2 | R1 | 2*R2 + R1 | C2 + 2*Clsb | C1 |
| 1 | 2*R1 | 2*R2 | C2 + Clsb | C1 + Clsb |
| 0 | 2*R1 + R2 | R2 | C2 | C1 + 2*Clsb |

For each sel code: Req(ref-vss)/Req(ref-vdd) = Ceq(ref-vdd)/Ceq(ref-vss)

The concept of employing the three reference values can be extended to any number of voltages according to application needs.

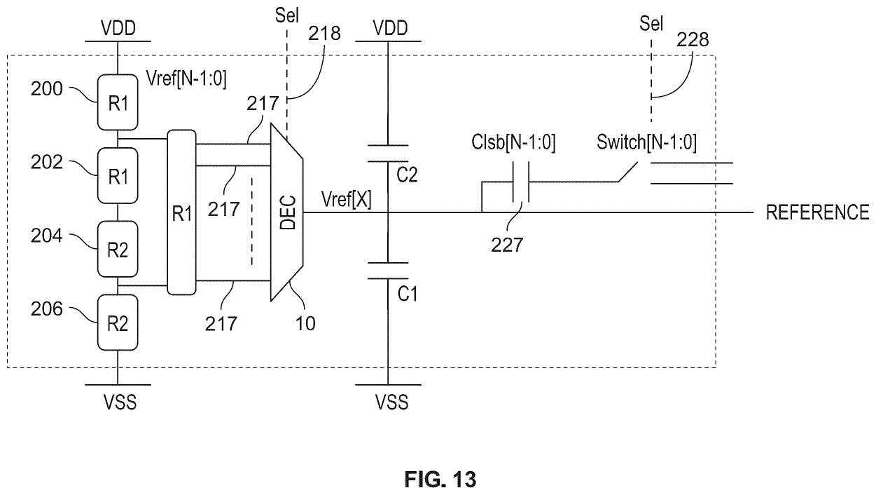

FIG. 13 presents a ladder in which a plurality of different voltage values can be selected by the ‘sel’ control according to some embodiments. N resistors (only resistors 200, 202, 204 and 206 are shown) are placed between VDD and Voltage Supply (VSS) and provide output to a decoder 210. A number of available voltage values 217 output from the group of resistors and can be chosen by for example a ‘sel’ control 218. A number of Clsb capacitors 227 in the array controlled also by a ‘sel’ control 228 and can be trimmed to maintain the ratio between equivalent resistances and capacitances.

In FIGS. 12-15, more than two capacitors and more than two resistors are used to produce multiple (typically selectable) reference signals. Each of different reference signals may be connected to a different set of resistors among the plurality of resistors, e.g. using select controls, decoders, or other circuitry.

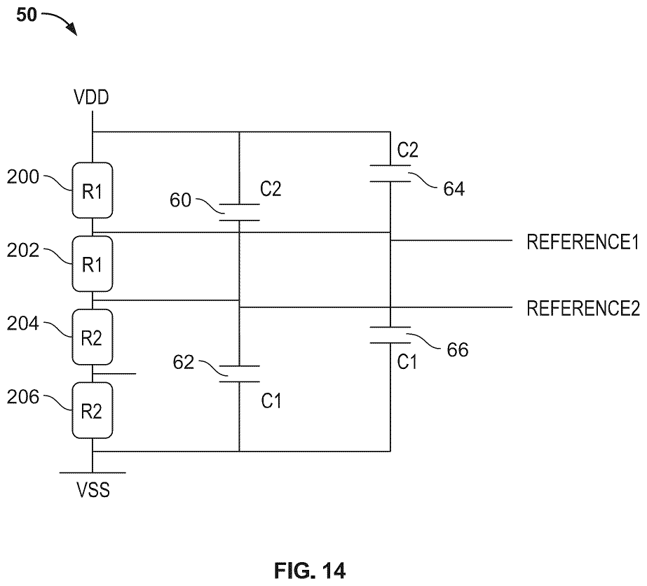

FIG. 14 presents an example circuit forming an all pass filter with multiple outputs according to some embodiments. In. FIG. 14, RefGen circuit 50 includes four resistors 200, 202, 204 and 206 four capacitors 60, 62, 64, and 66. If the ratio between equivalent resistances and capacitances maintained on each node the APF will work and maintain a voltage tracking.

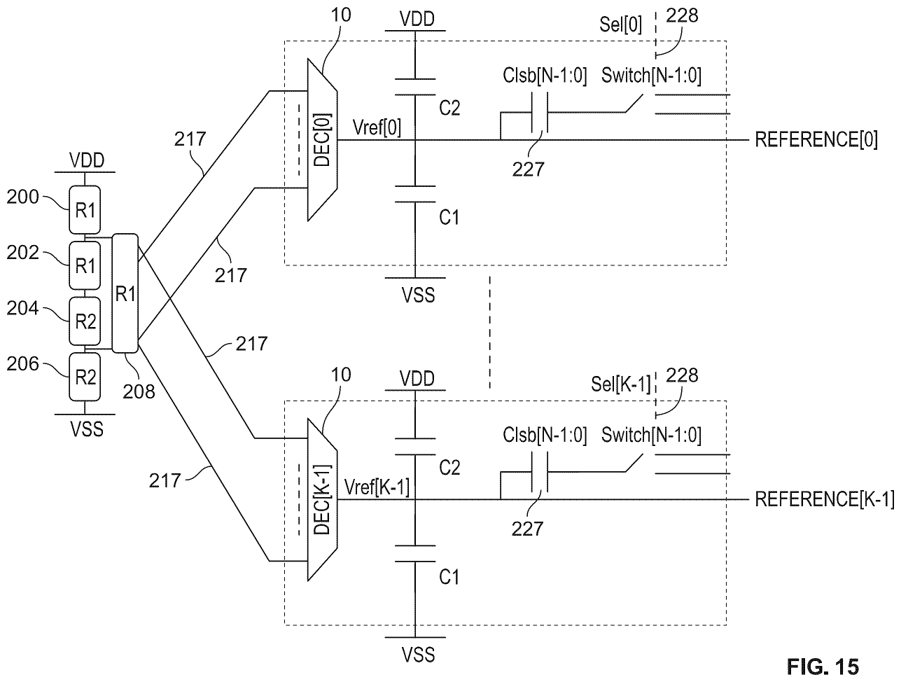

FIG. 15 presents an example implementation where a number of client circuits can accept a reference from a number of decoders connected to one resistor ladder, according to one embodiment of the invention. N resistors (four resistors 200, 202, 204, 206 are shown for clarity) and a resistor ladder 208 are placed between VDD and VSS and provide output to any number of decoders 210 (only two decoders are shown for clarity). Resistor ladder 208 may include multiple resistors in series. A number of available voltage values 217 output from the group of resistors 200, 202, 204, 206 and 208 and can be chosen. A number of Clsb capacitors 227 in arrays may be controlled also by a number of ‘sel’ controls 228. In FIG. 15, K client circuits can take the reference from K decoders connected to one resistor ladder. Each client can choose a reference value independently from other client choices by using a different ‘sel’ code. Each client configure its own ‘Clsb’ array and maintains the ratio between equivalent resistances and capacitances.

Embodiments of the invention include a method for operating an electronic circuit or a reference generator, such as the circuits described herein. Embodiments of such a method may include producing a reference signal using a set of resistors such as described in the various embodiments described herein, producing a source signal using a source circuit as described herein, and receiving the source signal and the reference signal at a receiving circuit connected to a positive supply voltage and a negative supply voltage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention. Further, specific features of certain embodiments may be used as features with other embodiments.

1. An electronic circuit comprising:
at least three resistors arranged in series;
a positive supply voltage connected to the resistors;
a negative supply voltage connected to the resistors, the at least three resistors producing a first reference signal and a second reference signal;
a first pair of capacitors arranged in parallel from the point of first reference signal and connected to first reference signal:
a second pair of capacitors arranged in parallel from the point of second reference signal and connected to second reference signal;
a first source circuit producing a first source signal and connected to the positive supply voltage and negative supply voltage;
a second source circuit producing a second source signal and connected to the positive supply voltage and negative supply voltage;
a first receiving circuit connected to the positive supply voltage and negative supply voltage, and receiving the first source signal and first reference signal; and
a second receiving circuit connected to the positive supply voltage and negative supply voltage, and receiving the second source signal and second reference signal.

2. The circuit of claim 1, wherein for two resistors of the at least three resistors and two capacitors connected to each reference signal R1/R2=C1/C2, R1 and R2 being equivalent resistance and C1 and C2 being capacitance.

3. The circuit of claim 1, wherein the first reference signal is substantially or exactly half of the first source signal.

4. The circuit of claim 1, wherein the at least three resistors form a resistor ladder, and each reference value is selected from a connection between two of the resistors.

5. The circuit of claim 1, wherein at least one of the capacitors is selectively controlled.

6. The circuit of claim 1 comprising more than two source circuits, a number of receiving circuits equal to the number of source circuits, and a number of reference signals equal to the number of source circuits, wherein each receiving circuit receives a source signal and a reference signal.

7. A method for operating an electronic circuit, the circuit comprising:
at least four capacitors;
at least three resistors arranged in series;
a positive supply voltage connected to the resistors;
a negative supply voltage connected to the resistors;
a first source circuit connected to the positive supply voltage and the negative supply voltage; and
a second source circuit connected to the positive supply voltage and the negative supply voltage, the method comprising:
producing a first reference signal using the resistors;
producing a second reference signal using the resistors;
producing a first source signal using the first source circuit;
producing a second source signal using the second source circuit;
receiving the first source signal and the first reference signal at a first receiving circuit connected to the positive supply voltage and negative supply voltage; and
receiving the second source signal and the second reference signal at a second receiving circuit connected to the positive supply voltage and negative supply voltage.

8. The method of claim 7, wherein for two resistors of the at least three resistors and two capacitors connected to each reference signal R1/R2=C1/C2, R1 and R2 being equivalent resistance and C1 and C2 being capacitance.

9. The method of claim 7, wherein the first reference signal is substantially or exactly half of the first source signal.

10. The method of claim 7, wherein the at least three resistors form a resistor ladder, and the first reference value is selected from a first connection between two of the resistors and the second reference value is selected from a second connection between two of the resistors.

11. The method of claim 7, wherein at least one of the capacitors is selectively controlled.

12. The method of claim 7 wherein the circuit comprises more than two source circuits, a number of receiving circuits equal to the number of source circuits, and wherein a number of reference signals equal to the number of source circuits is produced, wherein each receiving circuit receives a source signal and a reference signal.

13. A circuit comprising:
a plurality of capacitors;
a plurality of resistors arranged in series, the resistors producing a first reference signal and a second reference signal;
a first source circuit producing a first source signal and connected to a positive voltage and a negative voltage;
a second source circuit producing a second source signal and connected to the positive voltage and the negative voltage;
a first comparator connected to the positive voltage, the negative voltage, the first source signal and the first reference signal; and
a second comparator connected to the positive voltage, the negative voltage, the second source signal and the second reference signal.

14. The circuit of claim 13, wherein for two resistors of the resistors and two capacitors of the capacitors R1/R2=C1/C2, R1 and R2 being equivalent resistance and C1 and C2 being capacitance.

15. The circuit of claim 13, wherein the first reference signal is substantially or exactly half of the first source signal.

16. The circuit of claim 13, wherein the resistors form a resistor ladder, and the first reference value is selected from a connection between two of the resistors.

17. The circuit of claim 13, wherein at least one of the capacitors is selectively controlled.

18. The circuit of claim 13 wherein each of the first reference signal and second reference signal is connected to a different set of resistors among the plurality of resistors.

19. The circuit of claim 1, wherein each reference signal of the at least two reference signals is selected by a decoder.

20. The circuit of claim 1, wherein at least one capacitor is connected between each reference signal and a switch being controlled by a selection signal.

21. The circuit of claim 1, wherein for each reference signal R1eq/R2eq=C1eq/C2eq, R1eq being the equivalent resistance between the reference signal and negative supply voltage, R2eq being the equivalent resistance between the reference signal and positive supply voltage, C1eq being the equivalent capacitance between the reference signal and positive supply voltage, and C2eq being the equivalent capacitance between the reference signal and negative supply voltage.
